(19) United States
(12) Patent Application Publication
(10) Pub. No.: US 2023/0082000 A1
(43) Pub. Date: Mar. 16, 2023

(54) DISPLAY APPARATUS

(71) Applicant: Au Optronics Corporation, Hsinchu (TW)

(72) Inventors: Chun-Yu Lin, Hsinchu (TW); Ming-Lung Chen, Hsinchu (TW); Kun-Cheng Tien, Hsinchu (TW); Jia-Long Wu, Hsinchu (TW); YuTang Tsai, Hsinchu (TW)

(73) Assignee: Au Optronics Corporation, Hsinchu (TW)

(21) Appl. No.: 17/751,690

(22) Filed: May 24, 2022

Related U.S. Application Data
(60) Provisional application No. 63/244,748, filed on Sep. 16, 2021.

(30) Foreign Application Priority Data
Jan. 13, 2022 (TW) 111101382

(51) Int. Cl. H01L 25/075; H01L 33/44; H01L 33/62; H01L 33/58

(52) U.S. Cl. CPC H01L 25/0753; H01L 33/44; H01L 33/62; H01L 33/58; H01L 2933/0025; H01L 2933/0083; H01L 2933/0066; H01L 2933/0058

(57) ABSTRACT

A display apparatus includes a first conductive pattern layer, a first insulating pattern layer, a second conductive pattern layer, a second insulating pattern layer, pixel structures, and a light-absorbing pattern layer. The first insulating pattern layer is disposed on the first conductive pattern layer and has a first opening. The second conductive pattern layer is disposed on the first insulating pattern layer and has light-shielding conductive patterns arranged periodically. The second insulating pattern layer is disposed on the second conductive pattern layer and has a second opening overlapped with the first opening. The light-absorbing pattern layer covers at least a first sidewall defining the first opening and a second sidewall defining the second opening and separates the light-shielding conductive patterns of the second conductive pattern layer. The light-absorbing pattern layer has a light-transmitting opening overlapped with the first opening and the second opening.

### CROSS-REFERENCE TO RELATED APPLICATION

This application claims the priority benefit of U.S. Provisional Application No. 63/244,748, filed on Sep. 16, 2021, and Taiwan application serial no. 111101382, filed on Jan. 13, 2022. The entirety of each of the above-mentioned patent applications is hereby incorporated by reference herein and made a part of this specification.

### BACKGROUND OF THE INVENTION

### Field of the Invention

The invention relates to an optoelectronic apparatus, and more particularly, to a display apparatus.

### Description of Related Art

A transparent display apparatus has a certain degree of transparency, and a user may see the background information behind the transparent display apparatus through the transparent display apparatus, and at the same time may see the display information displayed by the transparent display apparatus. The transparent display apparatus may be applied to various occasions, such as vending machines, car windows, shop windows, and the like.

In order to allow the user to receive display information and background information at the same time, the transparent display apparatus has a non-transmitting region and a transmitting region. The non-transmitting region is used to arrange light-shielding members, such as electrodes, circuit traces, and the like. The transmitting region is used to allow background light to pass through, so that the user may receive the background information behind. Most of the light-shielding members disposed in the non-transmitting region are arranged periodically, and the periodically arranged light-shielding members readily form a plurality of regularly arranged micro-openings. When the background beam passes through these micro-openings, significant diffraction phenomenon occurs, thus reducing the quality of the background image. Therefore, how to reduce the diffraction phenomenon in the transparent display apparatus and maintain a certain degree of transparency in the transparent display apparatus is a major challenge currently faced.

### SUMMARY OF THE INVENTION

The invention provides a display apparatus with good see-through effect.

A display apparatus of the invention includes a substrate, a first conductive pattern layer, a first insulating pattern layer, a second conductive pattern layer, a second insulating pattern layer, a plurality of pixel structures, and a light-absorbing pattern layer. The substrate has a first region and a second region outside the first region. The first conductive pattern layer is disposed on the first region of the substrate. The first insulating pattern layer is disposed on the first conductive pattern layer and has a first opening. The first insulating pattern layer has a first sidewall defining the first opening. The second conductive pattern layer is disposed on the first insulating pattern layer, located in the first region of the substrate, and has a plurality of light-shielding conductive patterns arranged periodically. The second insulating pattern layer is disposed on the second conductive pattern layer and has a second opening. The second opening is overlapped with the first opening, and the second insulating pattern layer has a second sidewall defining the second opening. The plurality of pixel structures are disposed on the second insulating pattern layer. The light-absorbing pattern layer is disposed on the first region of the substrate. The light-absorbing pattern layer covers at least the first sidewall and the second sidewall and separates the plurality of light-shielding conductive patterns of the second conductive pattern layer. The light-absorbing pattern layer has a light-transmitting opening overlapped with the first opening and the second opening. The light-transmitting opening of the light-absorbing pattern layer is located in the second region of the substrate.

In an embodiment of the invention, the first conductive pattern layer has a plurality of light-shielding conductive patterns arranged periodically; in a top view of the display apparatus, the plurality of light-shielding conductive patterns of the first conductive pattern layer and the plurality of light-shielding conductive patterns of the second conductive pattern layer are alternately arranged; and the light-absorbing pattern layer further separates the plurality of light-shielding conductive patterns of the first conductive pattern layer.

In an embodiment of the invention, the light-absorbing pattern layer includes a sidewall portion covering the first sidewall of the first insulating pattern layer and the second sidewall of the second insulating pattern layer, separating the plurality of light-shielding conductive patterns of the first conductive pattern layer, and separating the plurality of light-shielding conductive patterns of the second conductive pattern layer. The sidewall portion includes a first sub-sidewall portion and a second sub-sidewall portion. In the top view of the display apparatus, an edge of the first sub-sidewall portion is located outside the corresponding light-shielding conductive pattern of the first conductive pattern layer, and an edge of the first sub-sidewall portion is substantially parallel to an edge of the corresponding light-shielding conductive pattern of the first conductive pattern layer. In the top view of the display apparatus, an edge of the second sub-sidewall portion is located outside the corresponding light-shielding conductive pattern of the second conductive pattern layer, and the edge of the second sub-sidewall portion is substantially parallel to an edge of the corresponding light-shielding conductive pattern of the second conductive pattern layer.

In an embodiment of the invention, the light absorption pattern layer further includes a first top portion and a second top portion. The first top portion is disposed on a top surface of the second insulating pattern layer facing away from the substrate, connected to the first sub-sidewall portion, and overlapped with the corresponding light-shielding conductive pattern of the first conductive pattern layer. The second top portion is disposed on the top surface of the second insulating pattern layer facing away from the substrate, connected to the second sub-sidewall portion, and overlapped with the corresponding light-shielding conductive pattern of the second conductive pattern layer.

In an embodiment of the invention, each of the pixel structures includes an electrode and a light-emitting element electrically connected to the electrode, the electrode belongs to a third conductive pattern layer, the third conductive pattern layer is disposed on the second insulating pattern layer, and the plurality of electrodes of the plurality of pixel structures are periodically arranged. The sidewall portion further includes a third sub-sidewall portion. In the top view of the display apparatus, an edge of the third sub-sidewall portion is located outside the corresponding electrode of the third conductive pattern layer, and the edge of the third sub-sidewall portion is substantially parallel to an edge of the corresponding electrode of the third conductive pattern layer.

In an embodiment of the invention, the light-absorbing pattern layer further includes a third top portion disposed on the top surface of the second insulating pattern layer facing away from the substrate, connected to the third sub-sidewall portion, and partially overlapped with the corresponding electrode of the third conductive pattern layer.

In an embodiment of the invention, the display apparatus further includes a light-shielding pattern layer and a third insulating pattern layer. The light-shielding pattern layer is disposed in the first region of the substrate, located between the first conductive pattern layer and the substrate, and shields the light-shielding conductive patterns of the first conductive pattern layer and the light-shielding conductive patterns of the second conductive pattern layer. The third insulating pattern layer is disposed on the light-shielding pattern layer and located between the first conductive pattern layer and the light-shielding pattern layer. The third insulating pattern layer has a third opening overlapped with the first opening and a third sidewall defining the third opening, and the light-absorbing pattern layer further covers the third sidewall.

In an embodiment of the invention, the display apparatus further includes an encapsulation layer covering the pixel structure and overlapped with the first opening of the first insulating pattern layer, the second opening of the second insulating pattern layer, and the light-transmitting opening of the light-absorbing pattern layer.

In an embodiment of the invention, the display apparatus further includes an encapsulation layer covering the pixel structure and filled in the first opening of the first insulating pattern layer, the second opening of the second insulating pattern layer, and the light-transmitting opening of the light-absorbing pattern layer.

In an embodiment of the invention, the first insulating pattern layer includes a first main portion and a first auxiliary portion. The first main portion is overlapped with the light-shielding conductive patterns of the first conductive pattern layer. The first auxiliary portion is located between the light-shielding conductive patterns of the first conductive pattern layer. The first sidewall defining the first opening of the first insulating pattern layer includes a sidewall of the first main portion and a sidewall of the first auxiliary portion opposite to and spaced apart from each other, and the light-absorbing pattern layer covers the sidewall of the first main portion of the first insulating pattern layer and the sidewall of the first auxiliary portion of the first insulating pattern layer.

In an embodiment of the invention, the first auxiliary portion of the first insulating pattern layer is located in the light-transmitting opening of the light-absorbing pattern layer.

In an embodiment of the invention, the second insulating pattern layer includes a second main portion and a second auxiliary portion. The second main portion is overlapped with the light-shielding conductive patterns of the first conductive pattern layer and disposed on the first main portion of the first insulating pattern layer. The second auxiliary portion is disposed on the first auxiliary portion of the first insulating pattern layer. The second sidewall defining the second opening of the second insulating pattern layer includes a sidewall of the second main portion and a sidewall of the second auxiliary portion opposite to and spaced apart from each other, and the light-absorbing pattern layer further covers the sidewall of the second main portion of the second insulating pattern layer and the sidewall of the second auxiliary portion of the second insulating pattern layer.

In an embodiment of the invention, the second auxiliary portion of the second insulating pattern layer is located in the light-transmitting opening of the light-absorbing pattern layer.

### BRIEF DESCRIPTION OF THE DRAWINGS

FIG. 1A to FIG. 1F are schematic top views of the manufacturing process of a display apparatus 10 of an embodiment of the invention.

FIG. 2A to FIG. 2F are schematic cross-sectional views of the manufacturing process of the display apparatus 10 of an embodiment of the invention.

FIG. 3A to FIG. 3F are schematic cross-sectional views of the manufacturing process of the display apparatus 10 of an embodiment of the invention.

FIG. 4 is a schematic top view of a light-shielding pattern layer 120 of an embodiment of the invention.

FIG. 5 is a schematic top view of a first conductive pattern layer 140 of an embodiment of the invention.

FIG. 6 is a schematic top view of a second conductive pattern layer 160 of an embodiment of the invention.

FIG. 7 is a schematic top view of a third conductive pattern layer 180 of an embodiment of the invention.

FIG. 8 shows a diffracted light spot formed by a coherent beam passing through the display apparatus 10 of an Example of the invention.

FIG. 9 shows a diffracted light spot formed by a coherent beam passing through the display apparatus of a Comparative example.

FIG. 10 shows reflection spectra of the display apparatus 10 of an Example of the invention and a display apparatus of a Comparative example.

FIG. 11 shows transmission spectra of the display apparatus 10 of an Example of the invention and a display apparatus of a Comparative example.

FIG. 12 is a schematic top view of a display apparatus 10A of another embodiment of the invention.

FIG. 13 is a schematic cross-sectional view of the display apparatus 10A of another embodiment of the invention.

FIG. 14 is a schematic cross-sectional view of the display apparatus 10A of another embodiment of the invention.

FIG. 15 is a schematic top view of a display apparatus 10B of another embodiment of the invention.

FIG. 16 is a schematic cross-sectional view of the display apparatus 10B of another embodiment of the invention.

FIG. 17 is a schematic cross-sectional view of the display apparatus 10B of another embodiment of the invention.

FIG. 18A to FIG. 18F are schematic cross-sectional views of the manufacturing process of the display apparatus 10 of an embodiment of the invention.

### DESCRIPTION OF THE EMBODIMENTS

Hereinafter, exemplary embodiments of the invention are described in detail, and examples of the exemplary embodiments are conveyed via the figures. Wherever possible, the same reference numerals are used in the figures and the descriptions to refer to the same or similar portions.

It should be understood that, when a layer, film, region, or an element of a substrate is “on” another element or “connected to” another element, the element may be directly on the other element or connected to the other element, or an intermediate element may also be present. On the other hand, when an element is “directly on another element” or “directly connected to” another element, an intermediate element is not present. As used in the present specification, “connected to” may refer to a physical and/or electrical connection. Furthermore, “electrically connected” or “coupled” may mean that other elements are present between two elements.

“About”, “similar”, or “substantially” used in the present specification include the value and the average value within an acceptable deviation range of a specific value confirmed by those having ordinary skill in the art, and the concerned measurement and a specific quantity (i.e., limitations of the measuring system) of measurement-related errors are taken into consideration. For example, “about” may represent within one or a plurality of standard deviations of the value, or within ±30%, ±20%, ±10%, or ±5%. Moreover, “about”, “similar”, or “substantially” used in the present specification may include a more acceptable deviation range or standard deviation according to optical properties, etching properties, or other properties, and one standard deviation does not need to apply to all of the properties.

Unless otherwise stated, all of the terminology used in the present specification (including technical and scientific terminology) have the same definition as those commonly understood by those skilled in the art of the invention. It should be further understood that, terminology defined in commonly-used dictionaries should be interpreted to have the same definitions in related art and in the entire specification of the invention, and are not interpreted as ideal or overly-formal definitions unless clearly stated as such in the present specification.

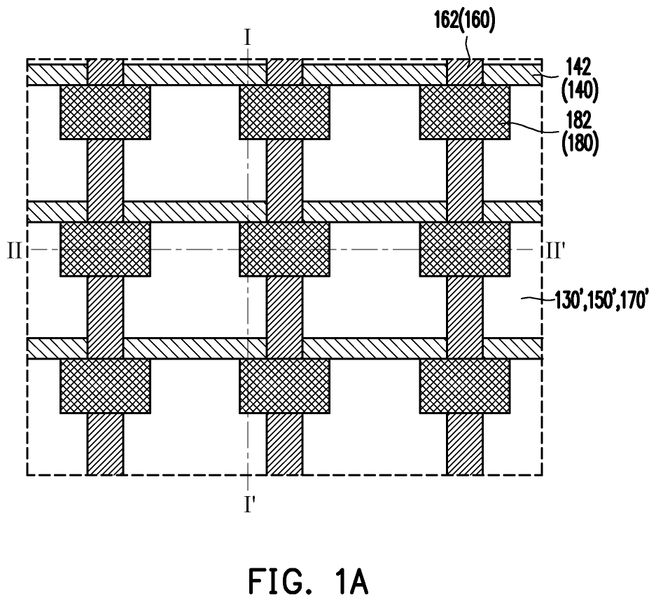

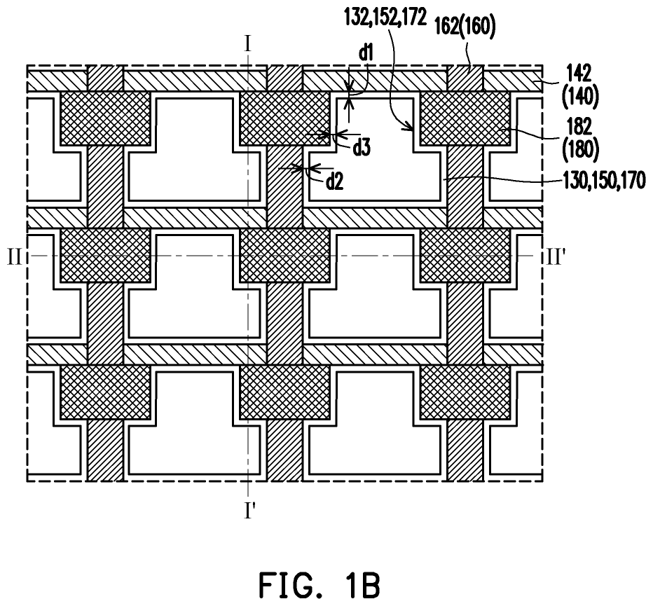

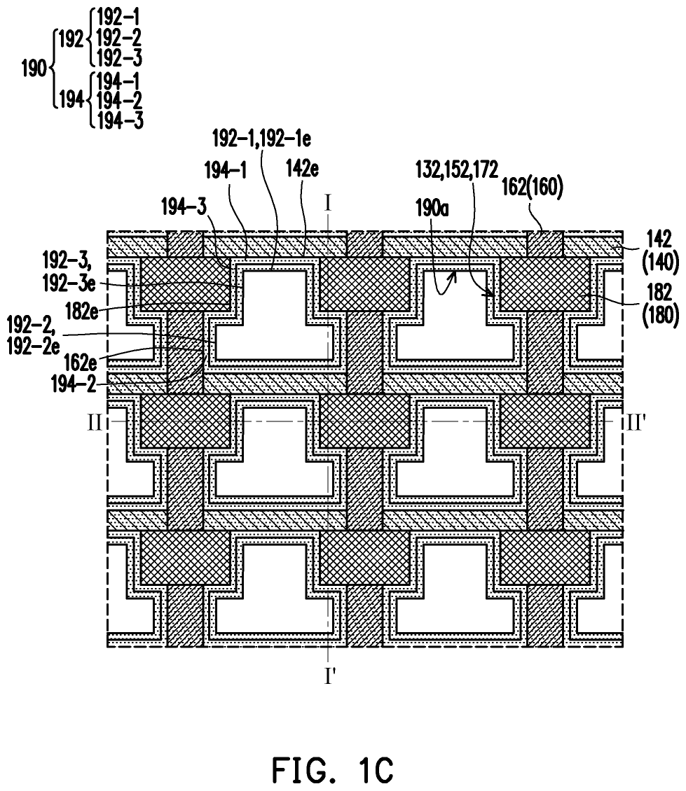

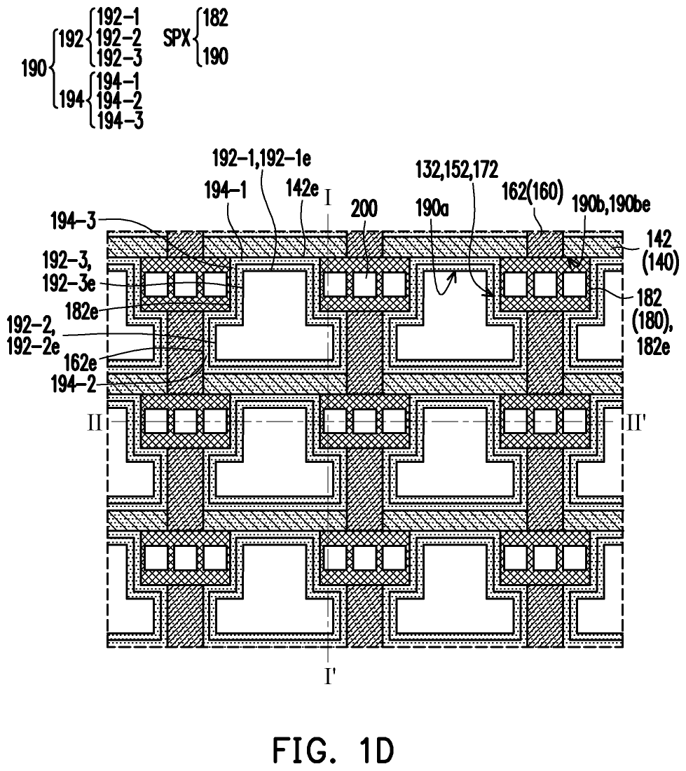

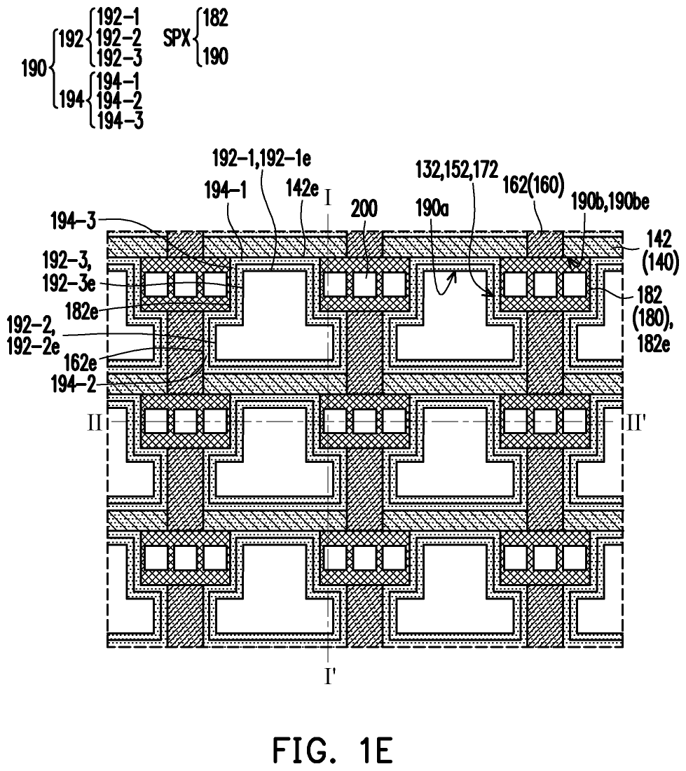

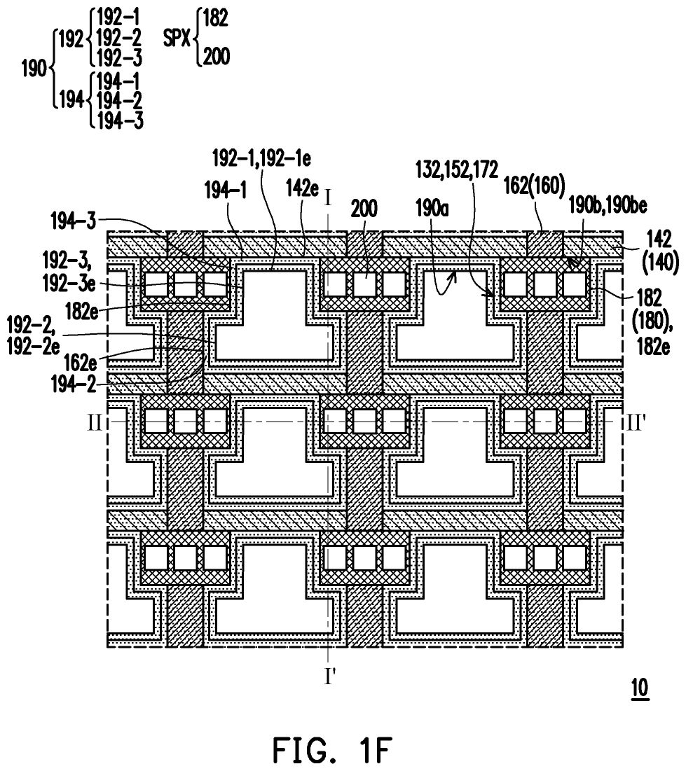

FIG. 1A to FIG. 1F are schematic top views of the manufacturing process of a display apparatus 10 of an embodiment of the invention.

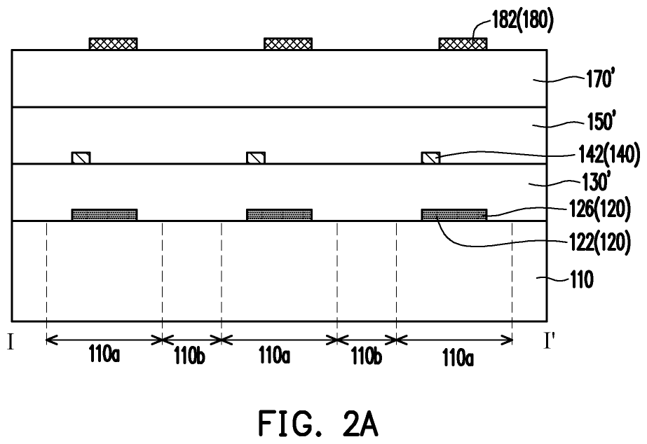

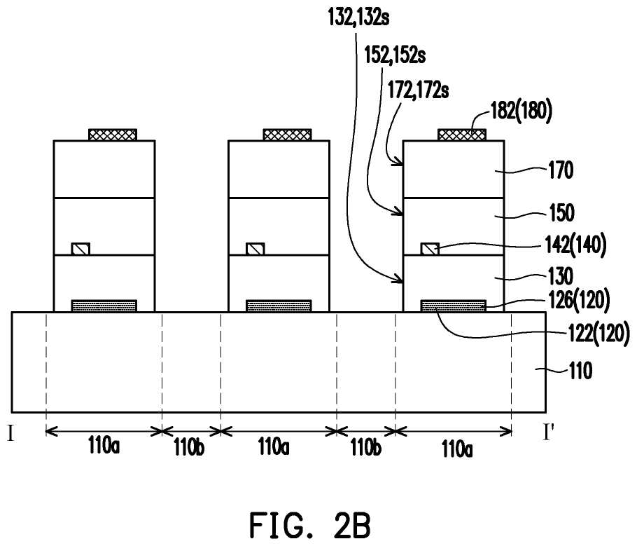

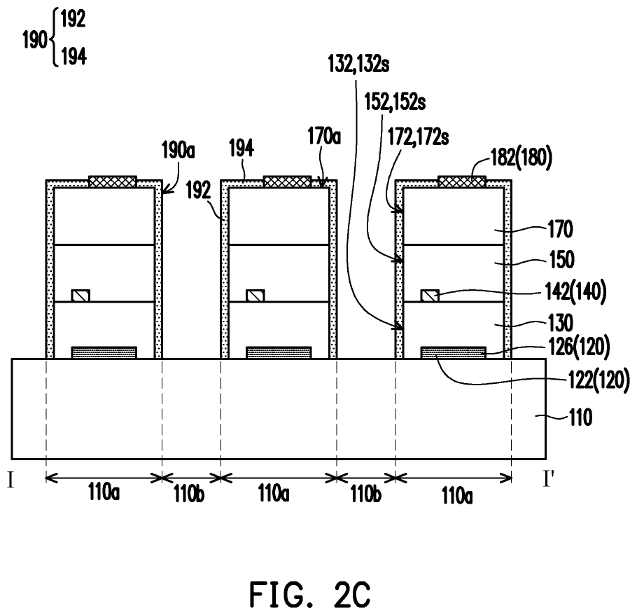

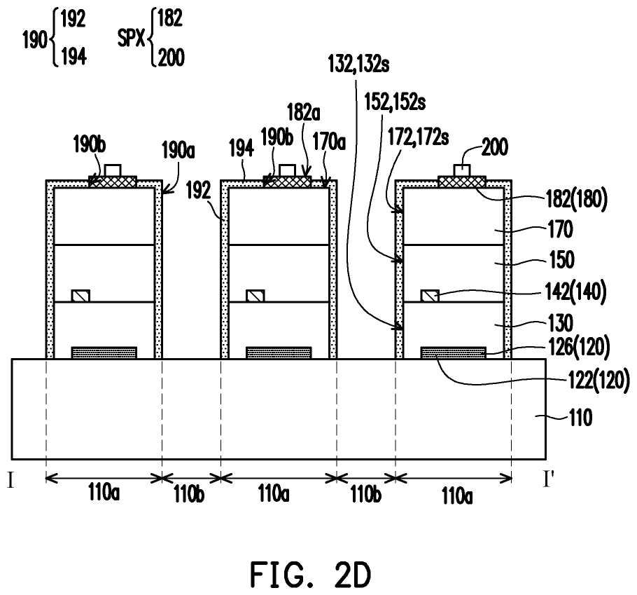

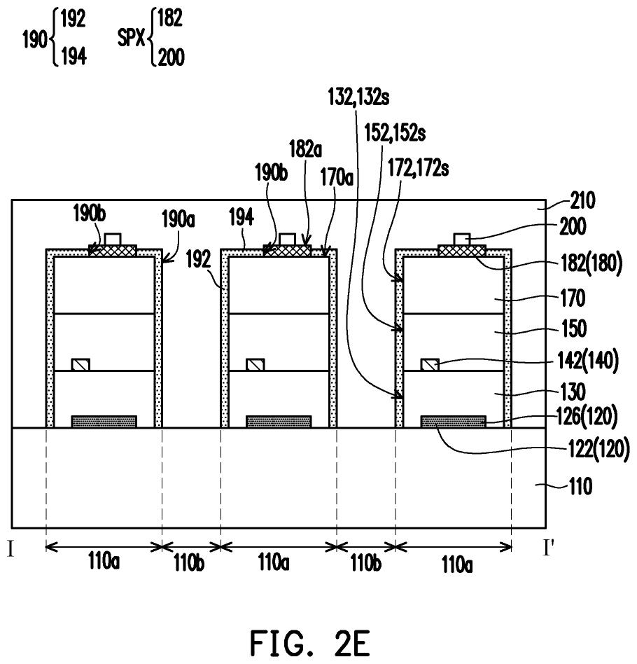

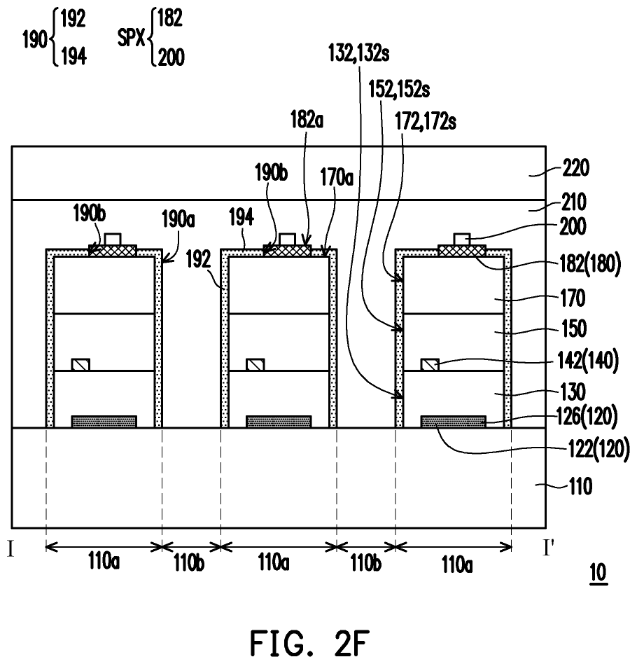

FIG. 2A to FIG. 2F are schematic cross-sectional views of the manufacturing process of the display apparatus 10 of an embodiment of the invention. FIG. 2A to FIG. 2F correspond to section line I-I′ of FIG. 1A to FIG. 1F, respectively.

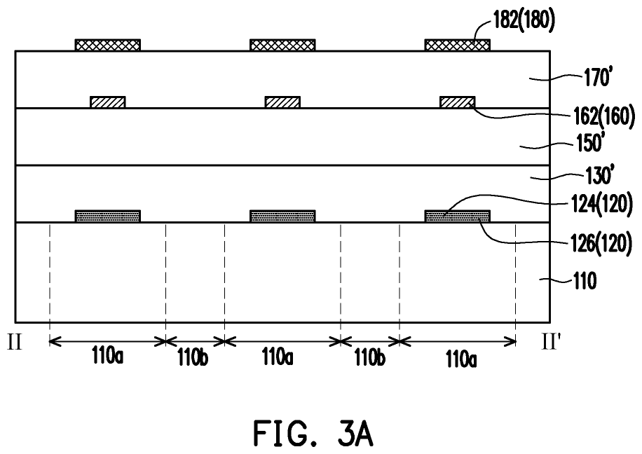

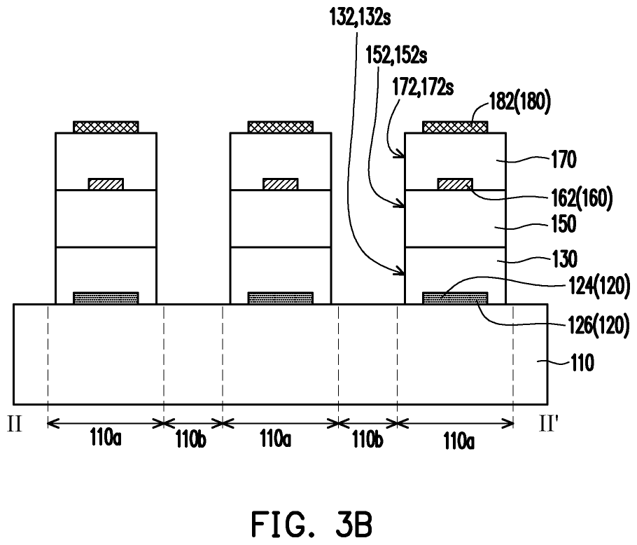

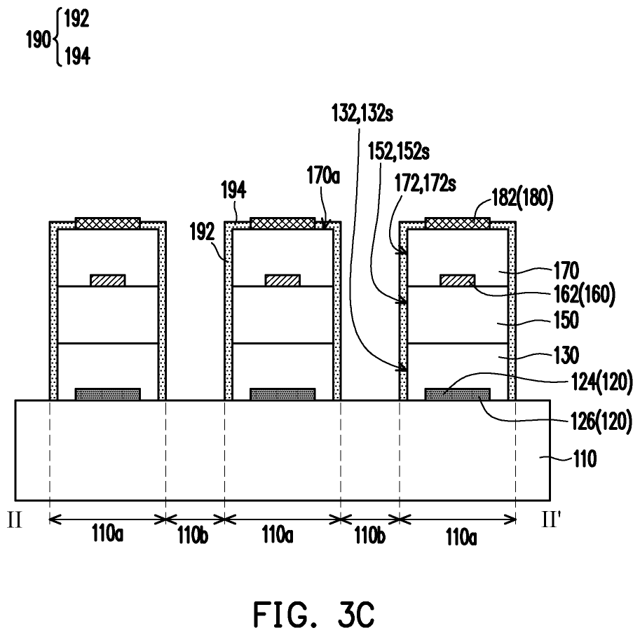

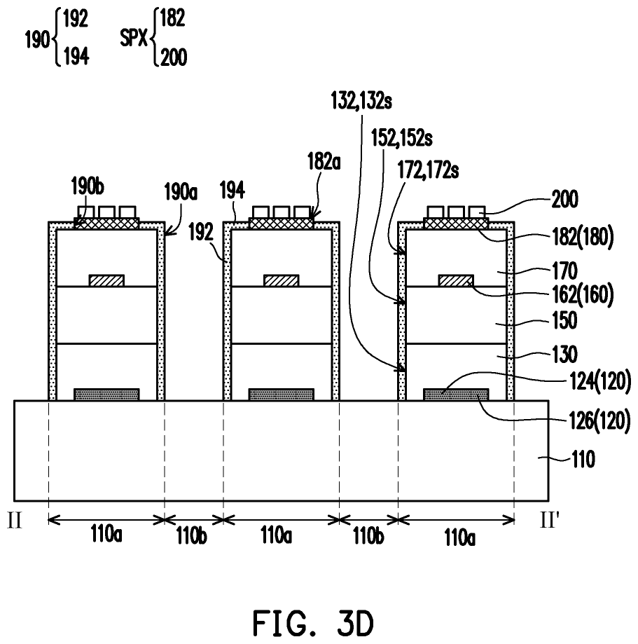

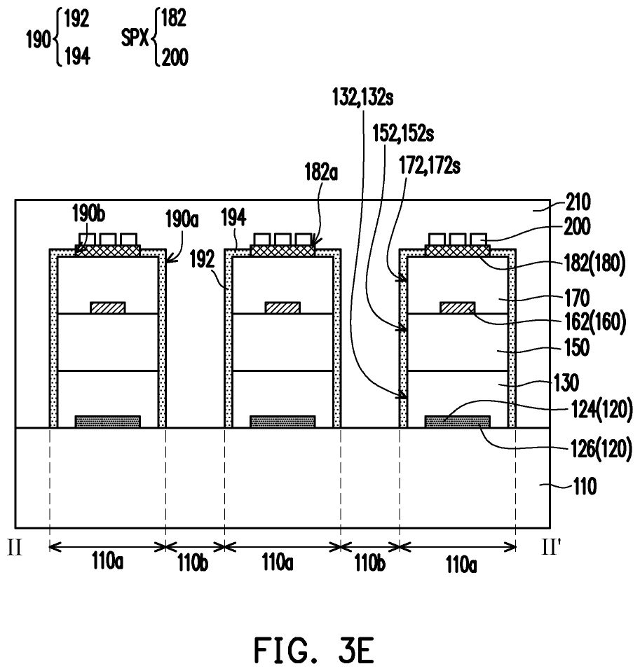

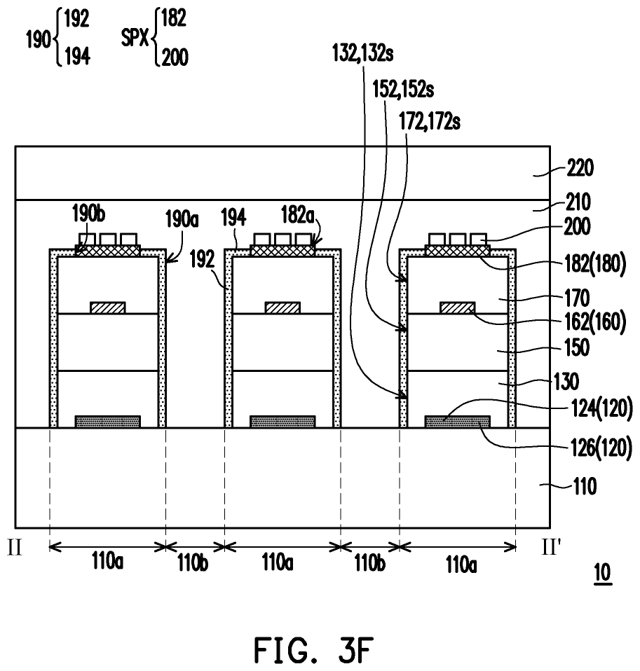

FIG. 3A to FIG. 3F are schematic cross-sectional views of the manufacturing process of the display apparatus 10 of an embodiment of the invention. FIG. 3A to FIG. 3F correspond to section line II-IF of FIG. 1A to FIG. 1F, respectively.

Referring first to FIG. 1A, FIG. 2A, and FIG. 3A, first, a substrate 110 is provided. The substrate 110 has a first region 110a and a second region 110b outside the first region 110a. The first region 110a is used to arrange the body of a light-shielding/light-absorbing member. The first region 110a may also be referred to as a non-transmitting region. The second region 110b is used for arranging the opening of the light-shielding/light-absorbing member and/or a light-transmitting member. The second region 110b may also be referred to as a transmitting region. In the present embodiment, the material of the substrate 110 is glass, for example. However, the invention is not limited thereto, and in other embodiments, the material of the substrate 110 may also be quartz, organic polymer, or other light-transmitting materials.

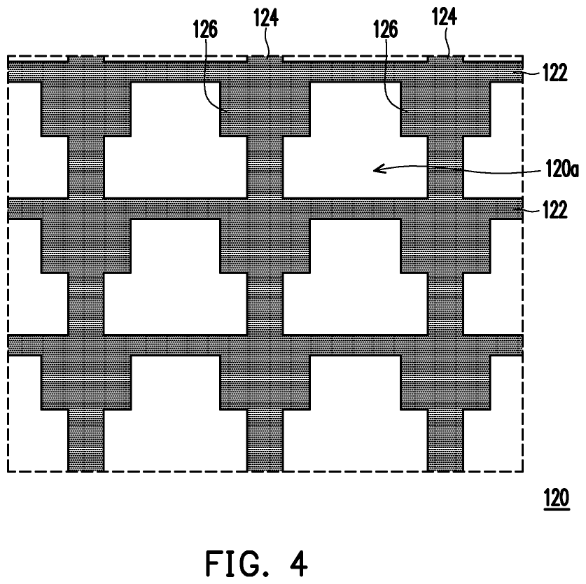

FIG. 4 is a schematic top view of a light-shielding pattern layer 120 of an embodiment of the invention.

Referring to FIG. 1A, FIG. 2A, FIG. 3A, and FIG. 4, next, a light-shielding pattern layer 120 is formed on the substrate 110. The light-shielding pattern layer 120 is disposed on the first region 110a of the substrate 110. In the present embodiment, the light-shielding pattern layer 120 includes a plurality of first light-shielding strips 122 arranged periodically and a plurality of second light-shielding strips 124 arranged periodically, wherein the plurality of first light-shielding strips 122 and the plurality of second light-shielding strips 124 are arranged alternately.

In the present embodiment, the light-shielding pattern layer 120 may further include a plurality of light-shielding patterns 126 arranged periodically, wherein each of the light-shielding patterns 126 is disposed beside at least one of one corresponding first light-shielding strip 122 and one corresponding second light-shielding strip 124. For example, in the present embodiment, each of the light-shielding patterns 126 may be optionally disposed beside the intersection of one corresponding first light-shielding strip 122 and second light-shielding strip 124, but the invention is not limited thereto. The light-shielding pattern layer 120 has a light-transmitting opening 120a (marked in FIG. 4). The light-transmitting opening 120a is defined by the solid edges of the light-shielding pattern layer 120. For example, in the present embodiment, the light-transmitting opening 120a may be defined by the edges of two adjacent first light-shielding strips 122, the edges of two adjacent second light-shielding strips 124, and the edges of two adjacent light-shielding patterns 126, but the invention is not limited thereto. In the present embodiment, the material of the light-shielding pattern layer 120 is, for example, metal. However, the invention is not limited thereto. In other embodiments, the material of the light-shielding pattern layer 120 may also be other materials capable of shielding light, and the material of the light-shielding pattern layer 120 may not necessarily be a conductive material.

Referring to FIG. 1A, FIG. 2A, and FIG. 3A, next, a third insulating material layer 130′ is formed on the substrate 110. The third insulating material layer 130′ is disposed on the first region 110a and the second region 110b of the substrate 110, and covers the light-shielding pattern layer 120. For example, in the present embodiment, the material of the third insulating material layer 130′ may be an inorganic material (for example, silicon oxide, silicon nitride, silicon oxynitride, or stacked layers of at least two of the above materials), an organic material, or a combination thereof.

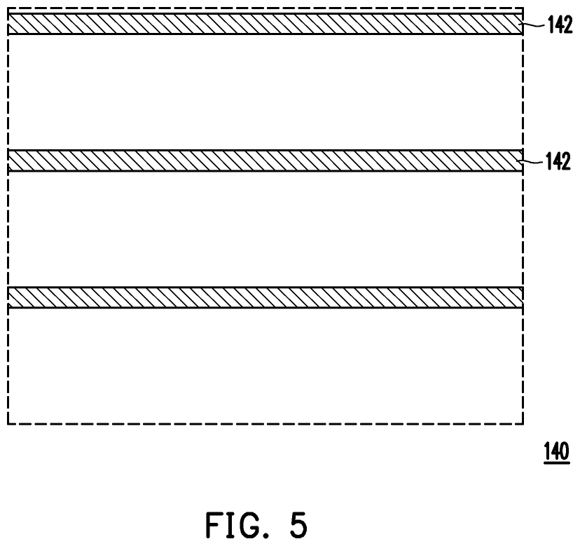

FIG. 5 is a schematic top view of a first conductive pattern layer 140 of an embodiment of the invention.

Referring to FIG. 1A, FIG. 2A, FIG. 3A, and FIG. 5, next, the first conductive pattern layer 140 is formed on the third insulating material layer 130′. The first conductive pattern layer 140 is disposed on the first region 110a of the substrate 110. The first conductive pattern layer 140 has a plurality of light-shielding conductive patterns 142 arranged periodically. Referring to FIG. 1A, FIG. 2A, FIG. 4, and FIG. 5, in the present embodiment, the plurality of first light-shielding strips 122 of the light-shielding pattern layer 120 shield the plurality of light-shielding conductive patterns 142 of the first conductive pattern layer 140 respectively. In the present embodiment, the plurality of light-shielding conductive patterns 142 of the first conductive pattern layer 140 are, for example, a plurality of gate lines. However, the invention is not limited thereto. In other embodiments, the plurality of light-shielding conductive patterns 142 of the first conductive pattern layer 140 may also be a plurality of data lines or other conductive elements. In the present embodiment, the material of the first conductive pattern layer 140 is, for example, metal. However, the invention is not limited thereto. In other embodiments, the material of the first conductive pattern layer 140 may also be other conductive materials capable of shielding light.

Referring to FIG. 1A, FIG. 2A, and FIG. 3A, next, a first insulating material layer 150′ is formed on the third insulating material layer 130′. The first insulating material layer 150′ is disposed on the first region 110a and the second region 110b of the substrate 110, and covers the first conductive pattern layer 140. For example, in the present embodiment, the material of the first insulating material layer 150′ may be an inorganic material (for example, silicon oxide, silicon nitride, silicon oxynitride, or stacked layers of at least two of the above materials), an organic material, or a combination thereof.

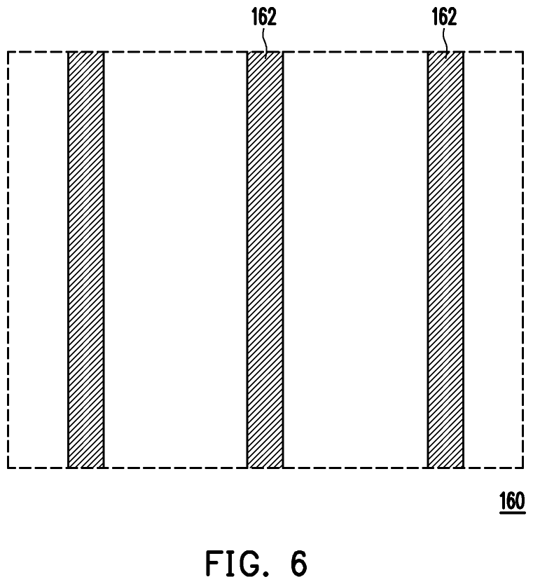

FIG. 6 is a schematic top view of a second conductive pattern layer 160 of an embodiment of the invention.

Referring to FIG. 1A, FIG. 3A, and FIG. 6, next, the second conductive pattern layer 160 is formed on the first insulating material layer 150′. The second conductive pattern layer 160 is disposed on the first region 110a of the substrate 110 and has a plurality of light-shielding conductive patterns 162 arranged periodically. Referring to FIG. 1A, FIG. 3A, FIG. 4, and FIG. 6, in the present embodiment, the plurality of second light-shielding strips 124 of the light-shielding pattern layer 120 shield the plurality of light-shielding conductive patterns 162 of the second conductive pattern layer 160 respectively. For example, in the present embodiment, the plurality of light-shielding conductive patterns 162 of the second conductive pattern layer 160 are, a plurality of data lines. However, the invention is not limited thereto. In other embodiments, the plurality of light-shielding conductive patterns 162 of the second conductive pattern layer 160 may also be a plurality of gate lines or other conductive elements. In the present embodiment, the material of the second conductive pattern layer 160 is, for example, metal. However, the invention is not limited thereto. In other embodiments, the material of the second conductive pattern layer 160 may also be other conductive materials capable of shielding light.

Referring to FIG. 1A, FIG. 2A, and FIG. 3A, next, a second insulating material layer 170′ is formed on the first insulating material layer 150′ and the second conductive pattern layer 160. The second insulating material layer 170′ is disposed on the first region 110a and the second region 110b of the substrate 110, and covers the second conductive pattern layer 160. For example, in the present embodiment, the material of the second insulating material layer 170′ may be an inorganic material (for example, silicon oxide, silicon nitride, silicon oxynitride, or stacked layers of at least two of the above materials), an organic material, or a combination thereof.

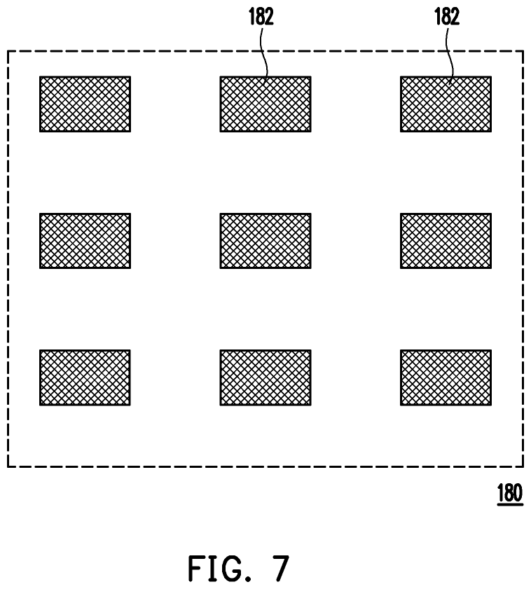

FIG. 7 is a schematic top view of a third conductive pattern layer 180 of an embodiment of the invention.

Referring to FIG. 1A, FIG. 2A, FIG. 3A, and FIG. 7, next, the third conductive pattern layer 180 is formed on the second insulating material layer 170′. The third conductive pattern layer 180 is disposed on the first region 110a of the substrate 110 and has a plurality of conductive patterns 182 arranged periodically. In the present embodiment, the plurality of conductive patterns 182 of the third conductive pattern layer 180 may optionally shield light, and the plurality of light-shielding patterns 126 of the light-shielding pattern layer 120 may shield the plurality of conductive patterns 182 of the third conductive pattern layer 180 respectively. For example, in the present embodiment, the plurality of conductive patterns 182 of the third conductive pattern layer 180 are a plurality of electrodes for electrically connecting with a light-emitting element 200 (shown in FIG. 1D, FIG. 2D, and FIG. 3D). However, the invention is not limited thereto. In other embodiments, the plurality of conductive patterns 182 of the third conductive pattern layer 180 may also be other conductive elements. In the present embodiment, the material of the third conductive pattern layer 180 is, for example, metal. However, the invention is not limited thereto. In other embodiments, the material of the third conductive pattern layer 180 may also be other conductive materials.

Referring to FIG. 1A to FIG. 1B, FIG. 2A to FIG. 2B, and FIG. 3A to FIG. 3B, next, the first insulating material layer 150′, the second insulating material layer 170′, and the third insulating material layer 130′ are patterned to form the first insulating pattern layer 150, the second insulating pattern layer 170, and the third insulating pattern layer 130. In the present embodiment, the first insulating material layer 150′, the second insulating material layer 170′, and the third insulating material layer 130′ may be optionally patterned using a laser drilling technique to form the first insulating pattern layer 150, the second insulating pattern layer 170, and the third insulating pattern layer 130 respectively having a first opening 152, a second opening 172, and a third opening 132. However, the invention is not limited thereto, and in other embodiments, the first opening 152, the second opening 172, and the third opening 132 may also be formed using other techniques.

Referring to FIG. 1B, FIG. 2B, and FIG. 3B, the first insulating pattern layer 150 is disposed on the first conductive pattern layer 140. The second conductive pattern layer 160 is disposed on the first insulating pattern layer 150. The second insulating pattern layer 170 is disposed on the second conductive pattern layer 160. The second opening 172 of the second insulating pattern layer 170 is overlapped with the first opening 152 of the first insulating pattern layer 150. The third insulating pattern layer 130 is disposed on the light-shielding pattern layer 120 and located between the first conductive pattern layer 140 and the light-shielding pattern layer 120. The third insulating pattern layer 130 has a third opening 132 overlapped with the first opening 152 of the first insulating pattern layer 150. The first insulating pattern layer 150 has a first sidewall 152s defining the first opening 152. The second insulating pattern layer 170 has a second sidewall 172s defining the second opening 172. The third insulating pattern layer 130 has a third sidewall 132s defining the third opening 132. In the present embodiment, the first sidewall 152s of the first insulating pattern layer 150, the second sidewall 172s of the second insulating pattern layer 170, and the third sidewall 132s of the third insulating pattern layer 130 are substantially aligned. That is, the first opening 152 of the first insulating pattern layer 150, the second opening 172 of the second insulating pattern layer 170, and the third opening 132 of the third insulating pattern layer 130 are substantially coincided.

Referring to FIG. 1B, in the present embodiment, in the top view, the edges of the first opening 152, the edges of the second opening 172, and the edges of the third opening 132 are located in the range enclosed by the body of the first conductive pattern layer 140, the body of the second conductive pattern layer 160, and the body of the third conductive pattern layer 180, and the edges of the first opening 152, the edges of the second opening 172, and the third opening 132 keep distances d1, d2, and d3 from the body of the first conductive pattern layer 140, the body of the second conductive pattern layer 160, and the body of the third conductive pattern layer 180.

Please refer to FIG. 1B, FIG. 2B, and FIG. 3B, in the present embodiment, the first insulating pattern layer 150, the second insulating pattern layer 170, and the third insulating pattern layer 130 cover the plurality of light-shielding conductive patterns 142 arranged periodically in the first conductive pattern layer 140, the plurality of light-shielding conductive patterns 162 arranged periodically in the second conductive pattern layer 160, and the plurality of first light-shielding strips 122 arranged periodically in the light-shielding pattern layer 120, the plurality of second light-shielding strips 124, and the plurality of light-shielding patterns 126, and the first opening 152 of the first insulating pattern layer 150, the second opening 172 of the second insulating pattern layer 170, and the third opening 132 of the third insulating pattern layer 130 expose the region not overlapped with the plurality of light-shielding conductive patterns 142 arranged periodically in the first conductive pattern layer 140, the plurality of light-shielding conductive patterns 162 arranged periodically in the second conductive pattern layer 160, the plurality of first light-shielding strips 122 arranged periodically in the light-shielding pattern layer 120, the plurality of second light-shielding strips 124, and the plurality of light-shielding patterns 126.

Please refer to FIG. 1C, FIG. 2C, and FIG. 3C, next, in the present embodiment, a light-absorbing pattern layer 190 is formed on at least the first sidewall 152s of the first insulating pattern layer 150 defining the first opening 152, the second sidewall 172s of the second insulating pattern layer 170 defining the second opening 172, and the third sidewall 132s of the third insulating pattern layer 130 defining the third opening 132.

Referring to FIG. 2C and FIG. 3C, in the present embodiment, the light-absorbing pattern layer 190 is disposed on the first region 110a of the substrate 110, the light-absorbing pattern layer 190 covers the first sidewall 152s, the second sidewall 172s, and the third sidewall 132s, and the light-absorbing pattern layer 190 separates the plurality of light-shielding conductive patterns 142 arranged periodically in the first conductive pattern layer 140, the plurality of light-shielding conductive patterns 162 arranged periodically in the second conductive pattern layer 160, and the plurality of conductive patterns 182 arranged periodically in the third conductive pattern layer 180.

Specifically, in the present embodiment, the light-absorbing pattern layer 190 includes a sidewall portion 192 covering the first sidewall 152s of the first insulating pattern layer 150, the second sidewall 172s of the second insulating pattern layer 170, and the third sidewall 132s of the third insulating pattern layer 130. The sidewall portion 192 of the light-absorbing pattern layer 190 separates the plurality of light-shielding conductive patterns 142 arranged periodically in the first conductive pattern layer 140, the plurality of light-shielding conductive patterns 162 arranged periodically in the second conductive pattern layer 160, and the plurality of conductive patterns 182 arranged periodically in the third conductive pattern layer 180.

Referring to FIG. 1C, more specifically, in the present embodiment, the sidewall portion 192 of the light-absorbing pattern layer 190 includes a first sub-sidewall portion 192-1, a second sub-sidewall portion 192-2, and a third sub-sidewall portion 192-3. In a top view, an edge 192-le of the first sub-sidewall portion 192-1 is located outside one corresponding light-shielding conductive pattern 142 of the first conductive pattern layer 140, and the edge 192-le of the first sub-sidewall portion 192-1 is substantially parallel to an edge 142e of one corresponding light-shielding conductive pattern 142 of the first conductive pattern layer 140. In a top view, an edge 192-2e of the second sub-sidewall portion 192-2 is located outside one corresponding light-shielding conductive pattern 162 of the first conductive pattern layer 160, and the edge 192-2e of the second sub-sidewall portion 192-2 is substantially parallel to an edge 162e of one corresponding light-shielding conductive pattern 162 of the second conductive pattern layer 160. In a top view, an edge 192-3e of the third sub-sidewall portion 192-3 is located outside one corresponding conductive pattern 182 of the third conductive pattern layer 180, and the edge 192-3e of the third sub-sidewall portion 192-3 is substantially parallel to an edge 182e of one corresponding conductive pattern 182 of the third conductive pattern layer 180.

Referring to FIG. 1C, FIG. 2C, and FIG. 3C, in the present embodiment, the light-absorbing pattern layer 190 may optionally further include a top portion 194 disposed on a top surface 170a of the second insulating pattern layer 170 facing away from the substrate 110. In the present embodiment, the top portion 194 of the light-absorbing pattern layer 190 may include a first top portion 194-1 (labeled in FIG. 1C), a second top portion 194-2 (labeled in FIG. 1C), and a third top portion 194-3 (labeled in FIG. 1C). The first top portion 194-1 is disposed on the top surface 170a of the second insulating pattern layer 170 facing away from the substrate 110, connected to the first sub-sidewall portion 192-1, and overlapped with one corresponding light-shielding conductive pattern 142 of the first conductive pattern layer 140. The second top portion 194-2 is disposed on the top surface 170a of the second insulating pattern layer 170 facing away from the substrate 110, connected to the second sub-sidewall portion 192-2, and overlapped with one corresponding light-shielding conductive pattern 162 of the second conductive pattern layer 160. The third top portion 194-3 is disposed on the top surface 170a of the second insulating pattern layer 170 facing away from the substrate 110, connected to the third sub-sidewall portion 192-3, and partially overlapped with one corresponding conductive pattern 182 of the third conductive pattern layer 180.

In the present embodiment, the light-absorbing pattern layer 190 has a light-transmitting opening 190a overlapped with the first opening 152 of the first insulating pattern layer 150, the second opening 172 of the second insulating pattern layer 170, and the third opening 132 of the third insulating pattern layer 130. The light-transmitting opening 190a of the light-absorbing pattern layer 190 is located in the second region 110b of the substrate 110. The light-transmitting opening 190a of the light-absorbing pattern layer 190 defines a transmitting region (i.e., the second region 110b).

Referring to FIG. 1C, in the present embodiment, the light-transmitting opening 190a of the light-absorbing pattern layer 190 may be optionally polygonal. In other words, in the present embodiment, the edges of the light-transmitting opening 190a of the light-absorbing pattern layer 190 have a plurality of corners. However, the invention is not limited thereto, and in other embodiments, the corners of the edges of the light-transmitting opening 190a of the light-absorbing pattern layer 190 may be rounded to reduce the diffraction effect of the background beam passing through the light-transmitting opening 190a. In other embodiments, the light-transmitting opening 190a may also be in the shape of a circle, an ellipse, or other shapes with arc-shaped edges.

Please refer to FIG. 1D, FIG. 2D, and FIG. 3D, in the present embodiment, next, a plurality of light-emitting elements 200 are disposed on the substrate 110, and the plurality of light-emitting elements 200 are electrically connected to the plurality of conductive patterns 182 of the third conductive pattern layer 180. Specifically, in the present embodiment, the light-absorbing pattern layer 190 has an auxiliary opening 190b exposing at least a portion of the conductive patterns 182; and the light-emitting elements 200 are disposed on at least a portion of the conductive patterns 182 exposed by the auxiliary opening 190b of the light-absorbing pattern layer 190.

In the present embodiment, the light-emitting elements 200 are, for example, micro light-emitting diodes (μLED). However, the invention is not limited thereto, and in other embodiments, the light-emitting elements 200 may also be other types of light-emitting elements. For example, in another embodiment, the light-emitting elements 200 may also be organic light-emitting elements including an organic electroluminescent layer. Moreover, it should be mentioned that, the invention does not limit the display apparatus 10 to necessarily include the light-emitting elements 200; and in another embodiment, the light-emitting elements 200 may also be replaced by non-self-light-emitting elements (not shown), wherein the non-self-light-emitting elements include a non-self-light-emitting display medium layer (e.g., but not limited to, a liquid-crystal layer).

In the present embodiment, each of pixel structures SPX includes an electrode (i.e., the conductive pattern 182) and the light-emitting element 200 electrically connected to the electrode, and the electrodes (i.e., the conductive patterns 182) belong to the third conductive pattern layer 180, and the third conductive pattern layer 180 is disposed on the second insulating pattern layer 170. In the present embodiment, in a top view, an edge 190be of the auxiliary opening 190b of the light-absorption pattern layer 190 coincides with the edge 182e of the electrode (i.e., the conductive pattern 182) corresponding to one pixel structure SPX. In the present embodiment, the top portion 194 of the light-absorbing pattern layer 190 may cover the top surface 170a of the second insulating pattern layer 170, but not cover a top surface 182a of the electrode (i.e., the conductive patterns 182), but the invention is not limited thereto.

Referring to FIG. 1E, FIG. 2E, and FIG. 3E, then, an encapsulation layer 210 is formed to cover the plurality of pixel structures SPX. The encapsulation layer 210 is overlapped with the first opening 152 of the first insulating pattern layer 150, the second opening 172 of the second insulating pattern layer 170, and the light-transmitting opening 190a of the light-absorbing pattern layer 190. In the present embodiment, the sidewall portion 192 of the light-absorbing pattern layer 190 does not completely fill the first opening 152 of the first insulating pattern layer 150, the second opening 172 of the second insulating pattern layer 170, and the third opening 132 of the third insulating pattern layer 130, and the encapsulation layer 210 may be filled in the first opening 152 of the first insulating pattern layer 150, the second opening 172 of the second insulating pattern layer 170, the third opening 132 of the third insulating pattern layer 130, and the light-transmitting opening 190a of the light-absorbing pattern layer 190. For example, in the present embodiment, the encapsulation layer 210 may be a thin-film encapsulation material, a die-bonding adhesive, or other encapsulation materials.

Referring to FIG. 1F, FIG. 2F, and FIG. 3F, then, in the present embodiment, a light-transmitting protective plate 220 may be optionally formed on the encapsulation layer 210. In the present embodiment, the light-transmitting protective plate 220 may optionally include an anti-reflection film (not shown), but the invention is not limited thereto. At this point, the display apparatus 10 of the present embodiment is completed.

It should be mentioned that, the display apparatus 10 includes the light-absorbing pattern layer 190 covering at least the first sidewall 152s of the first insulating pattern layer 150 and the second sidewall 172s of the second insulating pattern layer 170, and the light-absorbing pattern layer 190 at least separates the plurality of light-shielding conductive patterns 162 periodically arranged in the second conductive pattern layer 160. The background beam (not shown) from the rear of the display apparatus 10 is absorbed by the light-absorbing pattern layer 190 when passing through the plurality of light-shielding conductive patterns 162 arranged periodically in the second conductive pattern layer 160, and near-field diffraction is less likely to occur inside the display apparatus 10 from the background beam passing through the plurality of light-shielding conductive patterns 162 arranged periodically. Therefore, the background image viewed via the display apparatus 10 is clearer, and the see-through effect of the display apparatus 10 is good.

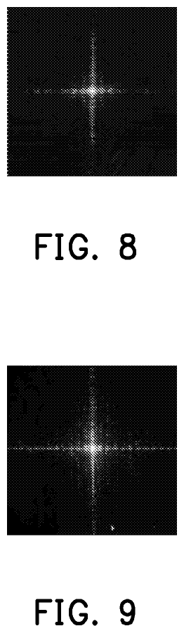

FIG. 8 shows a diffracted light spot formed by a coherent beam passing through the display apparatus 10 of an Example of the invention. FIG. 9 shows a diffracted light spot formed by a coherent beam passing through the display apparatus of a Comparative example.

The display apparatus of the Comparative example is similar to the display apparatus 10 of the Example, and the differences between the two are: the first insulating pattern layer, the second insulating pattern layer, and the third insulating pattern layer of the display apparatus of the Comparative example do not have the first opening, the second opening, and the third opening, and the display apparatus of the Comparative example does not include the light-absorbing pattern layer 190 of the display apparatus 10. Referring to FIG. 8 and FIG. 9, comparing the diffracted light spot formed by the coherent beam passing through the display apparatus 10 of the Example (as shown in FIG. 8) and the diffracted light spot formed by the display apparatus of the Comparative example (as shown in FIG. 9), it may be seen that, the degree of divergence of the diffracted light spot formed by the coherent beam passing through the display apparatus 10 of the Example is obviously slighter. It may be proved that the display apparatus 10 of the Example may effectively reduce the near-field diffraction effect between the film layers inside the display apparatus 10, thereby improving the clarity of the background image.

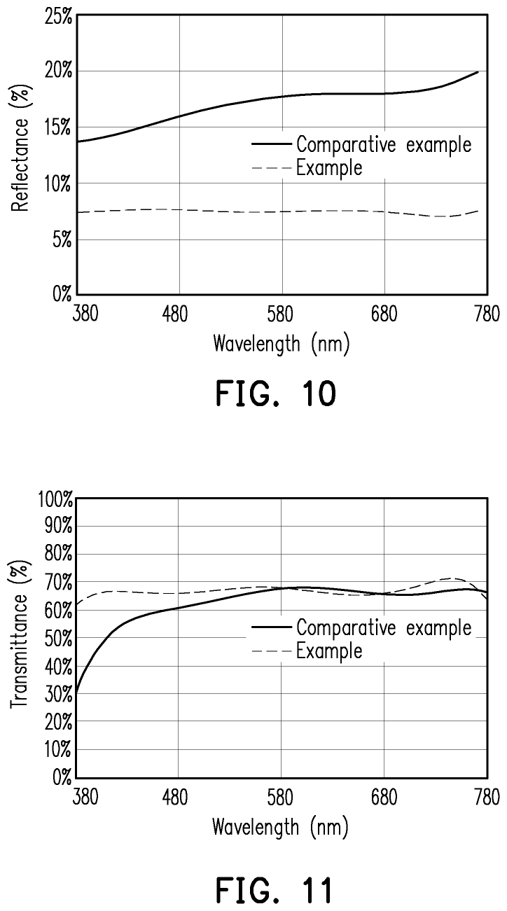

FIG. 10 shows reflection spectra of the display apparatus 10 of an Example of the invention and a display apparatus of a Comparative example. The display apparatus of the Comparative example corresponding to FIG. 10 is the display apparatus of the above Comparative example. For the differences between the display apparatus of the Comparative example and the display apparatus of the Example, please refer to the above description, which will not be repeated herein. Referring to FIG. 10, comparing the reflection spectra of the display apparatus 10 of the Example and the display apparatus of the Comparative example, it may be seen that, due to the light-absorbing pattern layer 190, the reflectance of the display apparatus 10 of the Example is significantly lower, and the lower reflectance helps to improve the visual effect of the display apparatus 10 under strong light.

FIG. 11 shows transmission spectra of the display apparatus 10 of an Example of the invention and a display apparatus of a Comparative example. The display apparatus of the Comparative example corresponding to FIG. 11 is the display apparatus of the above Comparative example. For the differences between the display apparatus of the Comparative example and the display apparatus 10 of the Example, please refer to the above description, which will not be repeated herein. Referring to FIG. 11, comparing the transmittance spectra of the display apparatus 10 of the Example and the display apparatus of the Comparative example, it may be seen that the transmittance of the display apparatus 10 of the Example is higher than the transmittance of the display apparatus of the Comparative example under most visible light wavelengths. That is to say, the transmittance of the display apparatus 10 of the Example is higher, thus helping to improve the see-through effect of the display apparatus 10. Moreover, the display apparatus of the Comparative example has a low transmittance at 380 nm to 480 nm. That is to say, the background beam passing through the display apparatus of the Comparative example lacks the components of violet light and blue light, and the background image seen through the display apparatus of the Comparative example is yellowish. In contrast to the display apparatus 10 of the Example, the transmittance of the display apparatus 10 of the Example is more uniform at each wavelength, and the issue of yellowing of the background image may be effectively alleviated.

It should be mentioned here that, the following embodiments adopt the reference numerals of the embodiments above and a portion of the content thereof, wherein the same reference numerals are used to represent the same or similar elements and descriptions of the same technical content are omitted. The omitted portions are as described in the embodiments above and are not repeated in the embodiments below.

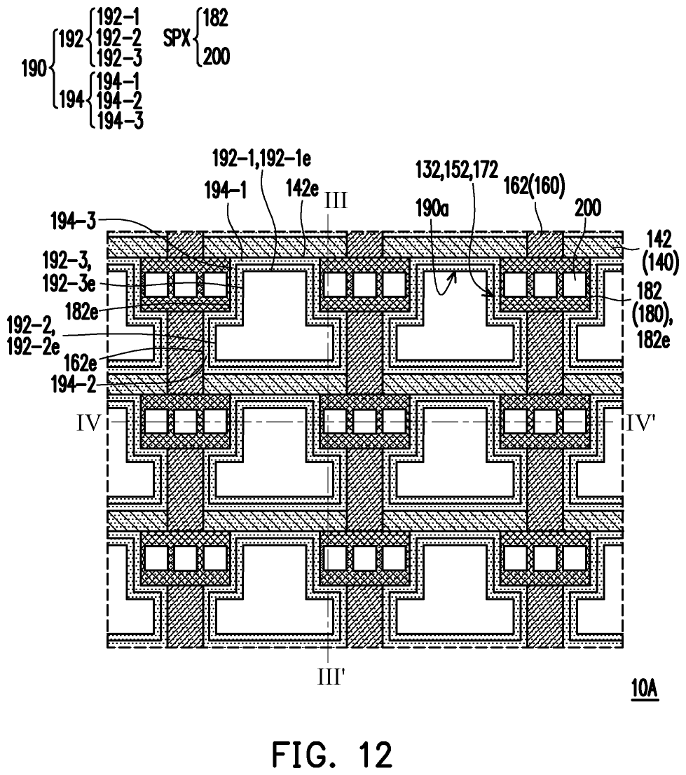

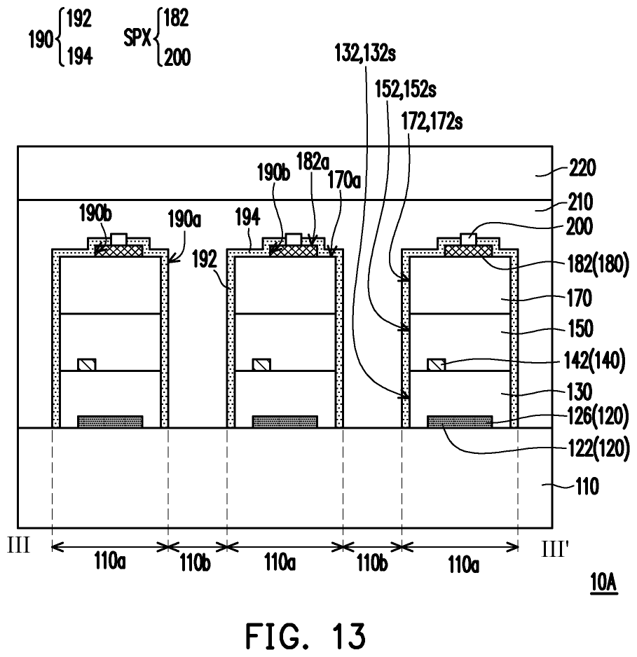

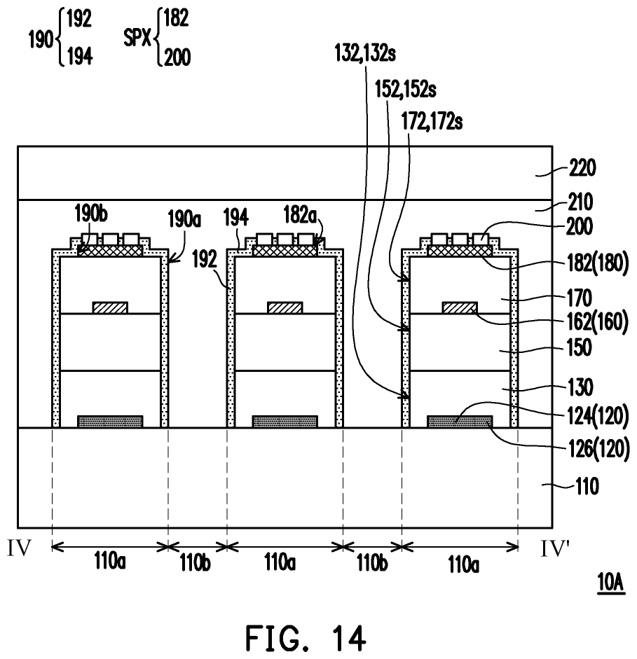

FIG. 12 is a schematic top view of a display apparatus 10A of another embodiment of the invention. FIG. 13 is a schematic cross-sectional view of the display apparatus 10A of another embodiment of the invention. FIG. 13 corresponds to section line of FIG. 12. FIG. 14 is a schematic cross-sectional view of the display apparatus 10A of another embodiment of the invention. FIG. 14 corresponds to section line IV-IV′ of FIG. 12.

The display apparatus 10A of FIG. 12, FIG. 13, and FIG. 14 is similar to the display apparatus 10 of FIG. 1F, FIG. 2F, and FIG. 3F, and the differences between the two are: the coverage area of the light-absorbing pattern layer 190 of the display apparatus 10A is different from the coverage area of the light-absorbing pattern layer 190 of the display apparatus 10.

Referring to FIG. 12, FIG. 13, and FIG. 14, specifically, in the present embodiment, the light-absorbing pattern layer 190 further covers at least a portion of the top surface 182a of the conductive patterns 182 of the third conductive pattern layer 180. In detail, in the present embodiment, the light-absorbing pattern layer 190 may cover the region in the top surface 182a of the conductive patterns 182 not occupied by the light-emitting element 200.

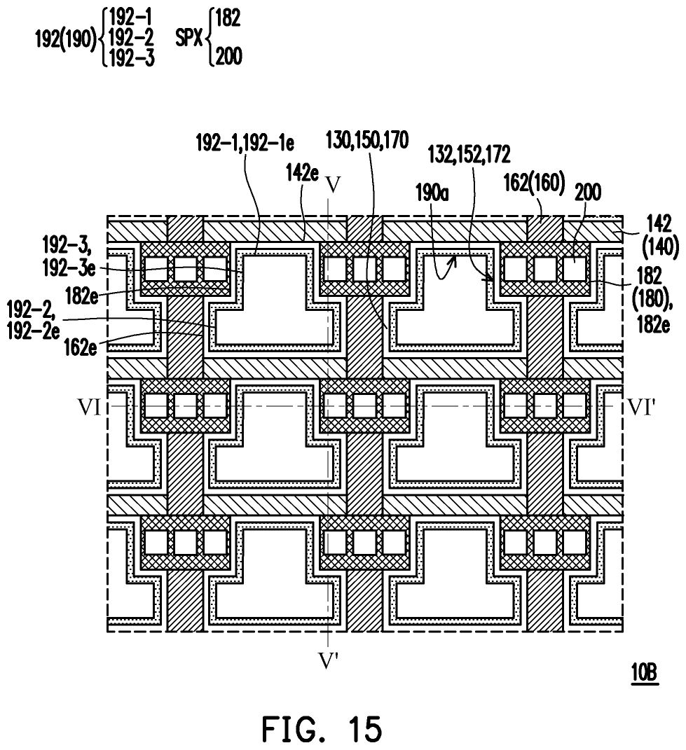

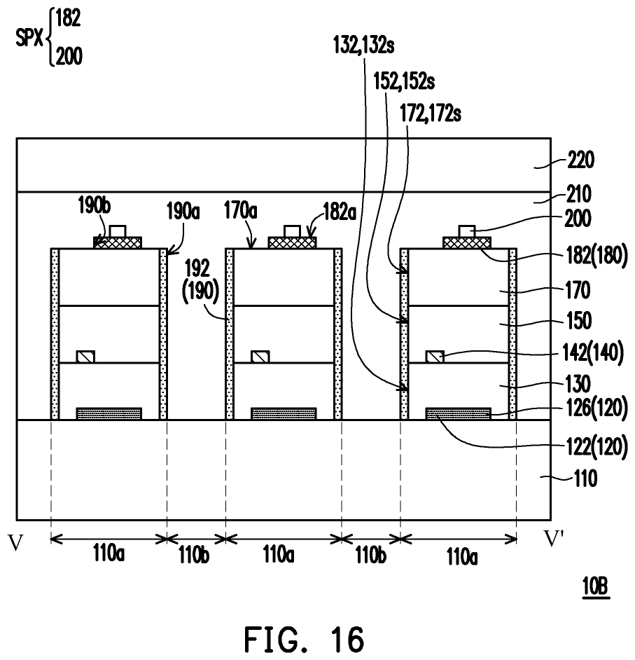

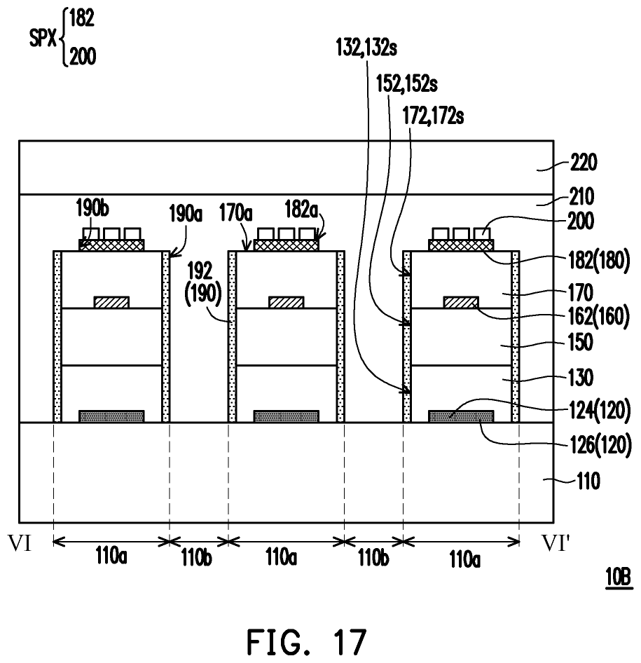

FIG. 15 is a schematic top view of a display apparatus 10B of another embodiment of the invention. FIG. 16 is a schematic cross-sectional view of the display apparatus 10B of another embodiment of the invention. FIG. 16 corresponds to section line V-V′ of FIG. 15. FIG. 17 is a schematic cross-sectional view of the display apparatus 10B of another embodiment of the invention. FIG. 17 corresponds to section line VI-VI′ of FIG. 15.

The display apparatus 10B of FIG. 15, FIG. 16, and FIG. 17 is similar to the display apparatus 10 of FIG. 1F, FIG. 2F, and FIG. 3F, and the differences between the two are: the coverage area of the light-absorbing pattern layer 190 of the display apparatus 10B is different from the coverage area of the light-absorbing pattern layer 190 of the display apparatus 10.

Please refer to FIG. 15, FIG. 16, and FIG. 17, specifically, in the present embodiment, the light-absorbing pattern layer 190 covers the first sidewall 152s of the first insulating pattern layer 150, the second sidewall 172s of the second insulating pattern layer 170, and the third sidewall 132s of the third insulating pattern layer 130. However, the light-absorbing pattern layer 190 does not cover the top surface 170a of the second insulating pattern layer 170 and the conductive patterns 182 of the third conductive pattern layer 180.

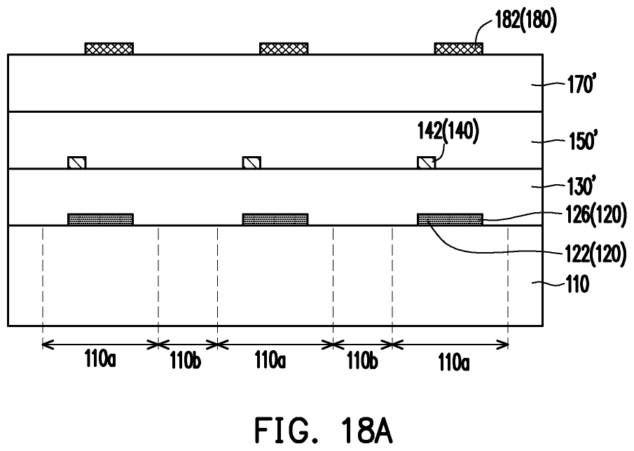

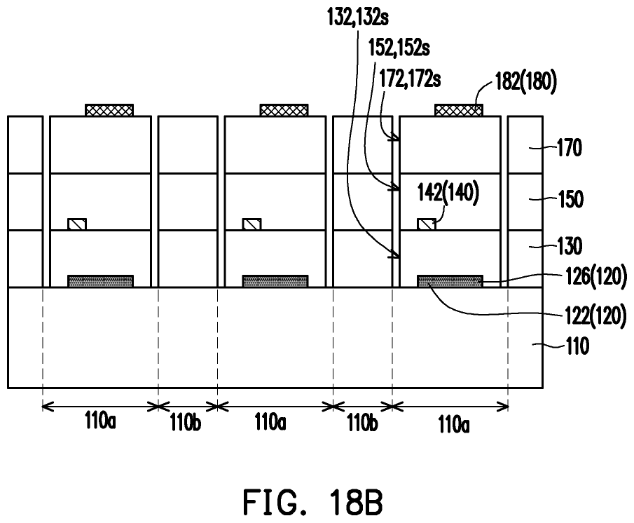

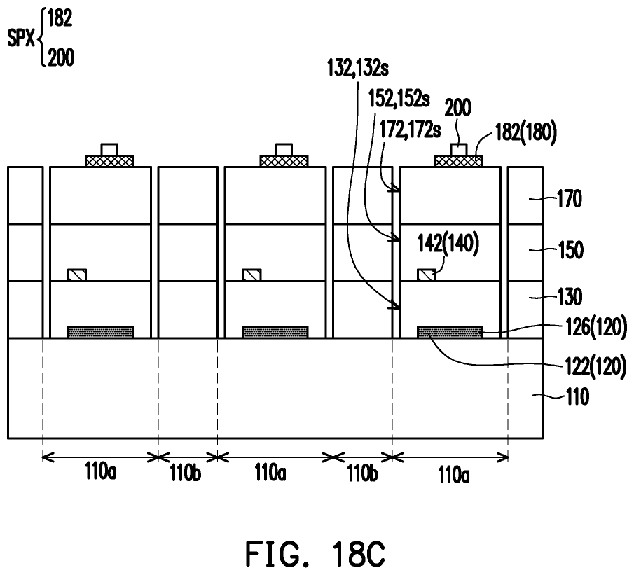

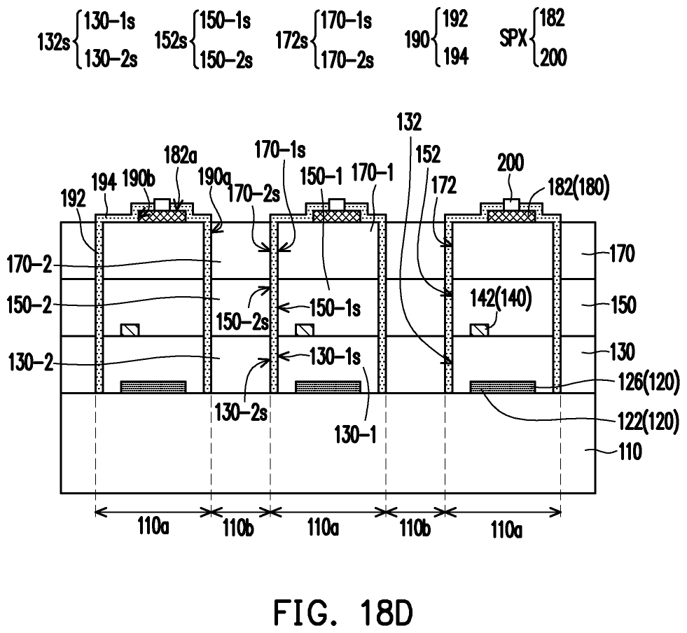

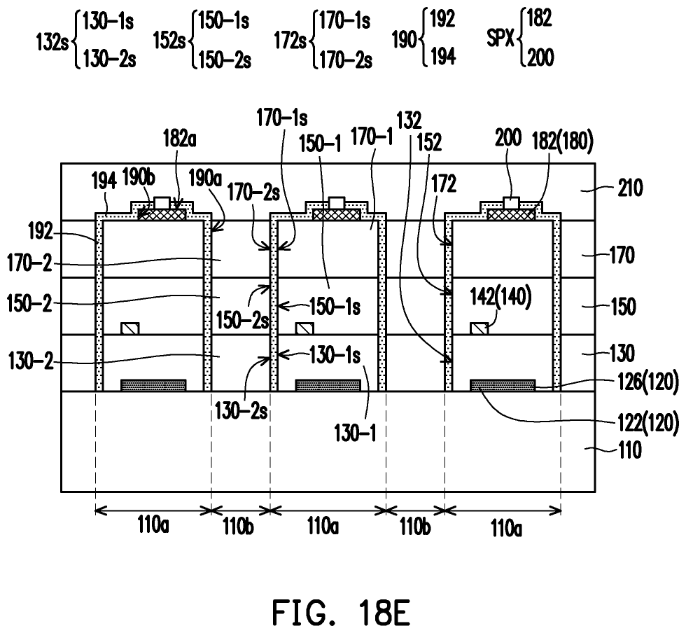

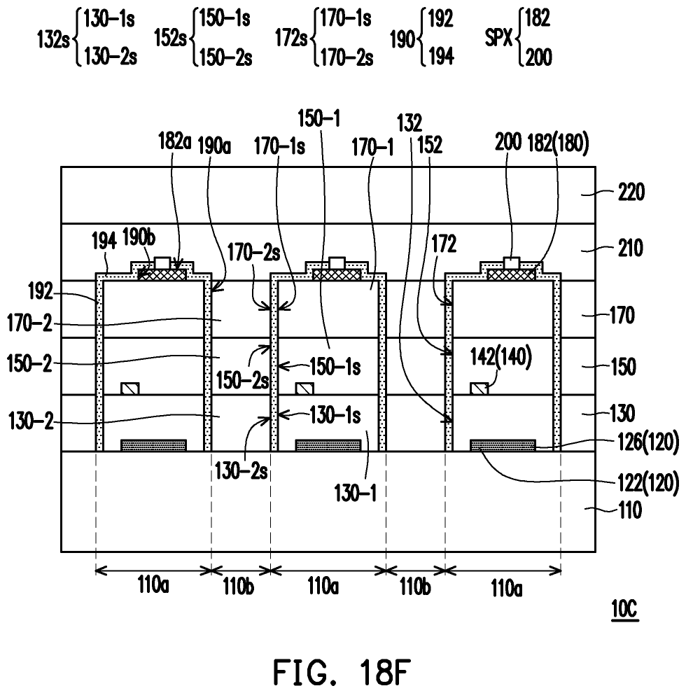

FIG. 18A to FIG. 18F are schematic cross-sectional views of the manufacturing process of the display apparatus 10 of an embodiment of the invention. The manufacturing process of the display apparatus 10C of FIG. 18A to FIG. 18F is similar to the manufacturing process of the display apparatus 10 of FIG. 2A to FIG. 2F, and the differences between the two are: the forming range of the first opening 152, the second opening 172, and the third opening 132 of the first insulating pattern layer 150, the second insulating pattern layer 170, and the third insulating pattern layer 130 of the display apparatus 10C is different from the forming range of the first opening 152, the second opening 172, and the third opening 132 of the first insulating pattern layer 150, the second insulating pattern layer 170, and the third insulating pattern layer 130 of the display apparatus 10. Description is provided below with examples and with reference to FIG. 18A to FIG. 18F.

Referring to FIG. 18A, first, the light-shielding pattern layer 120, the third insulating material layer 130′, the first conductive pattern layer 140, the first insulating material layer 150′, the second conductive pattern layer (not shown), the second insulating material layer 170′, and the third conductive pattern layer 180 are formed in sequence on the substrate 110.

Referring to FIG. 18B, next, the first insulating material layer 150′, the second insulating material layer 170′, and the third insulating material layer 130′ are patterned to form the first insulating pattern layer 150, the second insulating pattern layer 170, and the third insulating pattern layer 130 respectively having the first opening 152, the second opening 172, and the third opening 132.

Different from the previous embodiments, in the present embodiment, the first opening 152, the second opening 172, and the third opening 132 are not hollow openings, the first opening 152, the second opening 172, and the third opening 132 are annular openings, and the annular first opening 152, second opening 172, and third opening 132 are provided with a portion of the first insulating pattern layer 150, a portion of the second insulating pattern layer 170, and a portion of the third insulating pattern layer 130 therein.

Please refer to FIG. 18C, next, a plurality of light-emitting elements 200 are disposed on the substrate 110, and the plurality of light-emitting elements 200 are electrically connected to the plurality of conductive patterns 182 of the third conductive pattern layer 180. Each of the pixel structures SPX includes an electrode (i.e., the conductive pattern 182) and the light-emitting element 200 electrically connected to the electrode.

Referring to FIG. 18D, next, the light-absorbing pattern layer 190 is formed on at least the first sidewall 152s of the first insulating pattern layer 150 defining the first opening 152, the second sidewall 172s of the second insulating pattern layer 170 defining the second opening 172, and the third sidewall 132s of the third insulating pattern layer 130 defining the third opening 132.

Different from the previous embodiments, in the present embodiment, the first insulating pattern layer 150 includes a first main portion 150-1 and a first auxiliary portion 150-2, the first main portion 150-1 is overlapped with the light-shielding conductive patterns 142 of the first conductive pattern layer 140, the first auxiliary portion 150-2 is located between the light-shielding conductive patterns 142 of the first conductive pattern layer 140, the first sidewall 152s defining the first opening 152 of the first insulating pattern layer 150 includes a sidewall 150-1s of the first main portion 150-1 and a sidewall 150-2s of the first auxiliary portion 150-2 opposite to and spaced apart from each other, and the light-absorbing pattern layer 190 covers the sidewall 150-1s of the first main portion 150-1 of the first insulating pattern layer 150 and the sidewall 150-2s of the first auxiliary portion 150-2 of the first insulating pattern layer 150.

In the present embodiment, the second insulating pattern layer 170 includes a second main portion 170-1 and a second auxiliary portion 170-2, the second main portion 170-1 is overlapped with the light-shielding conductive pattern 142 of the first conductive pattern layer 140 and disposed on the first main portion 150-1 of the first insulating pattern layer 150, the second auxiliary portion 170-2 is disposed on the first auxiliary portion 150-2 of the first insulating pattern layer 150, the second sidewall 172s of the second opening 172 defining the second insulating pattern layer 170 includes the sidewall 170-1s of the second main portion 170-1 and the sidewall 170-2s of the second auxiliary portion 170-2 opposite to and spaced apart from each other, and the light-absorbing pattern layer 190 further covers the sidewall 170-1s of the second main portion 170-1 of the second insulating pattern layer 170 and the sidewall 170-2s of the second auxiliary portion 170-2 of the second insulating pattern layer 170.

In the present embodiment, the third insulating pattern layer 130 includes a third main portion 130-1 and a third auxiliary portion 130-2, the third main portion 130-1 covers the body of the light-shielding pattern layer 120 and is disposed between the first main portion 150-1 of the first insulating pattern layer 150 and the substrate 110, the third auxiliary portion 130-2 is disposed between the first auxiliary portion 150-2 of the first insulating pattern layer 150 and the substrate 110, the third sidewall 132s of the third opening 132 defining the third insulating pattern layer 130 includes the sidewall 130-1s of the third main portion 130-1 and the sidewall 130-2s of the third auxiliary portion 130-2 opposite to and spaced apart from each other, and the light-absorbing pattern layer 190 further covers the sidewall 130-1s of the third main portion 130-1 of the third insulating pattern layer 130 and the sidewall 130-2s of the third auxiliary portion 130-2 of the third insulating pattern layer 130.

In short, in the present embodiment, the light-absorbing pattern layer 190 may completely fill the first opening 152 of the first insulating pattern layer 150, the second opening 172 of the second insulating pattern layer 170, and the third opening 132 of the third insulating pattern layer 130, and the first auxiliary portion 150-2 of the first insulating pattern layer 150, the second auxiliary portion 170-2 of the second insulating pattern layer 170, and the third auxiliary portion 130-2 of the third insulating pattern layer 130 are located in the light-transmitting opening 190a of the light-absorbing pattern layer 190. In the present embodiment, the light-absorbing pattern layer 190 is formed using an ink jet printing process instead of a lithography process.

Referring to FIG. 18E, then, the encapsulation layer 210 is formed to cover the plurality of pixel structures SPX. Referring to FIG. 18F, lastly, the light-transmitting protective plate 220 is formed on the encapsulation layer 210. At this point, a display apparatus 10D of the present embodiment is completed.

What is claimed is:

1. A display apparatus, comprising:
a substrate having a first region and a second region outside the first region;
a first conductive pattern layer disposed on the first region of the substrate;
a first insulating pattern layer disposed on the first conductive pattern layer and having a first opening, wherein the first insulating pattern layer has a first sidewall defining the first opening;
a second conductive pattern layer disposed on the first insulating pattern layer, located in the first region of the substrate, and having a plurality of light-shielding conductive patterns arranged periodically;
a second insulating pattern layer disposed on the second conductive pattern layer and having a second opening, wherein the second opening is overlapped with the first opening, and the second insulating pattern layer has a second sidewall defining the second opening;
a plurality of pixel structures disposed on the second insulating pattern layer; and
a light-absorbing pattern layer disposed on the first region of the substrate, wherein the light-absorbing pattern layer at least covers the first sidewall and the second sidewall and separates the light-shielding conductive patterns of the second conductive pattern layer, the light-absorbing pattern layer has a light-transmitting opening overlapped with the first opening and the second opening, and the light-transmitting opening of the light-absorbing pattern layer is located in the second region of the substrate.

2. The display apparatus of claim 1, wherein the first conductive pattern layer has a plurality of light-shielding conductive patterns arranged periodically; in a top view of the display apparatus, the light-shielding conductive patterns of the first conductive pattern layer and the light-shielding conductive patterns of the second conductive pattern layer are alternately arranged; and the light-absorbing pattern layer further separates the light-shielding conductive patterns of the first conductive pattern layer.

3. The display apparatus of claim 2, wherein the light-absorbing pattern layer comprises:
a sidewall portion covering the first sidewall of the first insulating pattern layer and the second sidewall of the second insulating pattern layer, separating the light-shielding conductive patterns of the first conductive pattern layer, and separating the light-shielding conductive patterns of the second conductive pattern layer, wherein the sidewall portion comprises:
a first sub-sidewall portion, wherein, in the top view of the display apparatus, an edge of the first sub-sidewall portion is located outside a corresponding light-shielding conductive pattern of the first conductive pattern layer; and
a second sub-sidewall portion, wherein, in the top view of the display apparatus, an edge of the second sub-sidewall portion is located outside a corresponding light-shielding conductive pattern of the second conductive pattern layer.

4. The display apparatus of claim 3, wherein the light-absorbing pattern layer further comprises:
a first top portion disposed on a top surface of the second insulating pattern layer facing away from the substrate, connected to the first sub-sidewall portion, and overlapped with the corresponding light-shielding conductive pattern of the first conductive pattern layer; and
a second top portion disposed on the top surface of the second insulating pattern layer facing away from the substrate, connected to the second sub-sidewall portion, and overlapped with the corresponding light-shielding conductive pattern of the second conductive pattern layer.

5. The display apparatus of claim 3, wherein each of the pixel structures comprises an electrode and a light-emitting element electrically connected to the electrode, the electrode belongs to a third conductive pattern layer, the third conductive pattern layer is disposed on the second insulating pattern layer, the plurality of electrodes of the pixel structures are periodically arranged, and the sidewall portion further comprises:
a third sub-sidewall portion, wherein, in the top view of the display apparatus, an edge of the third sub-sidewall portion is located outside a corresponding electrode of the third conductive pattern layer.

6. The display apparatus of claim 5, wherein the light-absorbing pattern layer further comprises:
a third top portion disposed on the top surface of the second insulating pattern layer facing away from the substrate, connected to the third sub-sidewall portion, and partially overlapped with the corresponding electrode of the third conductive pattern layer.

7. The display apparatus of claim 2, further comprising:
a light-shielding pattern layer disposed in the first region of the substrate, located between the first conductive pattern layer and the substrate, and shielding the light-shielding conductive patterns of the first conductive pattern layer and the light-shielding conductive patterns of the second conductive pattern layer; and
a third insulating pattern layer disposed on the light-shielding pattern layer and located between the first conductive pattern layer and the light-shielding pattern layer, wherein the third insulating pattern layer has a third opening overlapped with the first opening and a third sidewall defining the third opening, and the light-absorbing pattern layer further covers the third sidewall.

8. The display apparatus of claim 1, further comprising:
an encapsulation layer covering the pixel structures and overlapped with the first opening of the first insulating pattern layer, the second opening of the second insulating pattern layer, and the light-transmitting opening of the light-absorbing pattern layer.

9. The display apparatus of claim 1, further comprising:
an encapsulation layer covering the pixel structures and filled in the first opening of the first insulating pattern layer, the second opening of the second insulating pattern layer, and the light-transmitting opening of the light-absorbing pattern layer.

10. The display apparatus of claim 1, wherein the first insulating pattern layer comprises:
a first main portion overlapped with the light-shielding conductive patterns of the first conductive pattern layer; and
a first auxiliary portion located between the light-shielding conductive patterns of the first conductive pattern layer;
wherein the first sidewall defining the first opening of the first insulating pattern layer comprises a sidewall of the first main portion and a sidewall of the first auxiliary portion opposite to and spaced apart from each other, and the light-absorbing pattern layer covers the sidewall of the first main portion of the first insulating pattern layer and the sidewall of the first auxiliary portion of the first insulating pattern layer.

11. The display apparatus of claim 10, wherein the first auxiliary portion of the first insulating pattern layer is located in the light-transmitting opening of the light-absorbing pattern layer.

12. The display apparatus of claim 11, wherein the second insulating pattern layer comprises:
a second main portion overlapped with the light-shielding conductive patterns of the first conductive pattern layer and disposed on the first main portion of the first insulating pattern layer; and
a second auxiliary portion disposed on the first auxiliary portion of the first insulating pattern layer;
wherein the second sidewall defining the second opening of the second insulating pattern layer comprises a sidewall of the second main portion and a sidewall of the second auxiliary portion opposite to and spaced apart from each other, and the light-absorbing pattern layer further covers the sidewall of the second main portion of the second insulating pattern layer and the sidewall of the second auxiliary portion of the second insulating pattern layer.

13. The display apparatus of claim 12, wherein the second auxiliary portion of the second insulating pattern layer is located in the light-transmitting opening of the light-absorbing pattern layer.
